(19) United States
(12) Patent Application Publication
(10) Pub. No.: US 2018/0158821 A1
(43) Pub. Date: Jun. 7, 2018

(54) GATE STRUCTURES WITH LOW RESISTANCE

(71) Applicant: GLOBALFOUNDRIES INC., Grand Cayman (KY)

(72) Inventors: Changyong XIAO, Shanghai (CN); Xusheng WU, Ballston Lake, NY (US); Min-hwa CHI, San Jose, CA (US); Jie CHEN, Shanghai (CN)

(21) Appl. No.: 15/370,555

(22) Filed: Dec. 6, 2016

(51) Int. Cl. H01L 27/092; H01L 21/8238

(52) U.S. Cl. CPC H01L 27/092; H01L 29/42376; H01L 21/823842; H01L 21/82385

(57) ABSTRACT

The present disclosure relates to semiconductor structures and, more particularly, to gate structures with low resistance and methods of manufacture. The structure includes: an nFET device formed in a first cavity having a first volume which is filled with conductive material; and a pFET device forming in a second cavity having a second volume greater than the first volume. The second volume being filled with the conductive material.

### FIELD OF THE INVENTION

The present disclosure relates to semiconductor structures and, more particularly, to gate structures with low resistance and methods of manufacture.

### BACKGROUND

A replacement metal gate process is widely used for several different technology nodes including, e.g., 20 nm node and below. In fact, a metal gate last scheme, i.e., replacement metal gate process, has become widely accepted as an industry standard for 20 nm and below Si technology nodes.

By using the replacement metal gate process for smaller technology nodes, e.g., 20 nm and below, the gate resistance between an nFET device and a pFET device is unpaired. In other words, the resultant nFET device and pFET device have a significant resistance difference, e.g., asymmetric resistance, which causes different device performance. And, replacement metal gate processes can result in a high gate resistance becoming more serious as the gates become narrower in the smaller technology nodes.

The asymmetry of gate resistance results from insufficient space in a cavity formed after removal of the dummy gate material. For example, in the replacement metal gate process, certain volume of work function (WF) material is required to reach the targeted Vt, but during the fill process, the gate sidewall is covered by WF material which consumes room or leaves no room for conduction material (e.g., tungsten or low-resistance materials) filling in the gate cavity formed from a removal of the dummy gate material.

### SUMMARY

In an aspect of the disclosure, a structure comprises: an nFET device formed in a first cavity having a first volume which is filled with conductive material; and a pFET device forming in a second cavity having a second volume greater than the first volume. The second volume being filled with the conductive material.

In an aspect of the disclosure, a structure comprises: an nFET device in a first cavity having a n-type diffusion barrier material, an n-type workfunction metal and a first volume of conductive fill material; and a pFET device in a second cavity having p-type workfunction metal and a second volume of conductive fill material which is greater than the first volume of the conductive fill material.

In an aspect of the disclosure, a method comprises: filling a first cavity and a second cavity with a first workfunction material and sacrificial dummy gate material; removing the sacrificial dummy gate material and the first workfunction material from the first cavity, while protecting the first workfunction material and the sacrificial dummy gate material in the second cavity; filling the first cavity with second workfunction material and conductive material; removing the sacrificial dummy gate material from the second cavity; and filling the second cavity with the conductive material over the first workfunction material.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows sacrificial dummy gate structures, amongst other features, and respective fabrication processes in accordance with aspects of the present disclosure.

FIGS. 2A and 2B show alternative structures and respective fabrication processes in accordance with aspects of the present disclosure.

FIG. 3 shows material layers deposited within a cavity on an nFET side of the structure, amongst other features, and respective fabrication processes in accordance with aspects of the present disclosure.

FIG. 4 shows metal gate material in an nFET cavity, amongst other features, and respective fabrication processes in accordance with aspects of the present disclosure.

FIGS. 5A and 5B show alternative structures and respective fabrication processes in accordance with aspects of the present disclosure.

FIG. 6 shows metal gate material in pFET cavity, amongst other features, and respective fabrication processes in accordance with aspects of the present disclosure.

FIGS. 7-10 show alternative embodiments and respective fabrication processes in accordance with aspects of the present disclosure.

### DETAILED DESCRIPTION

The present disclosure relates to semiconductor structures and, more particularly, to gate structures with low resistance and methods of manufacture. More specifically, the present disclosure relates to gate structures with low and equivalent gate resistance which are fabricated using single or dual sacrificial-dummy gate processes. Advantageously, in embodiments, the single or dual sacrificial-dummy gate processes described herein provides a method to remove redundant workfunction (WF) materials from a gate cavity in order to allow more conduction material fill. This, in turn, reduces gate resistance for particular devices, while also allowing tuning of the nFET and pFET devices.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask.

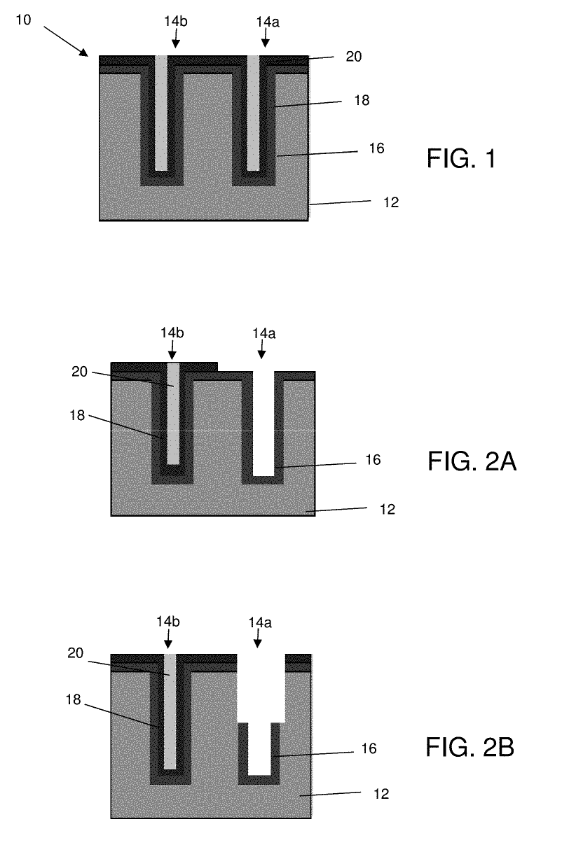

FIG. 1 shows sacrificial dummy gate structures, amongst other features, and respective fabrication processes in accordance with aspects of the present disclosure. More specifically, the structure 10 shown in FIG. 1 includes cavities 14a and 14b formed in an insulator material 12, e.g., oxide based material. In embodiments, the cavities 14a, 14b are gate locations, with some gates contemplated being on the top of shallow trench insulation regions and other gates formed on the fin structures, as should be understood by those of skill in the art. In embodiments, the cavities 14a and 14b can be used for the formation of nFET devices and pFET devices, respectively.

In embodiments, the cavities 14a and 14b are formed after removal of polysilicon dummy gate using standard replacement metal gate (RMG) processes. For example, in replacement gate processes, a dielectric material, e.g., dielectric material 16, and dummy gate material, e.g., poly material, can be patterned, followed by, in embodiments, sidewall formation, e.g., on the gate structure. In embodiments, a workfunction metal, e.g., work function material 18, can also be patterned with the dielectric material and dummy gate material, e.g., poly material. The insulator material 12 can then be formed over the patterned dummy gate material, e.g., sacrificial material. The poly material can then be removed by a selective etching process, forming the cavities 14a, 14b.

Still referring to FIG. 1, in embodiments, each of the cavities 14a, 14b can also be filled with different materials using conventional deposition processes, after removal of material to form the cavities 14a, 14b. For example, high-k gate dielectric material 16 and p-type workfunction material 18 can be deposited by a conventional blanket deposition, e.g., chemical vapor deposition (CVD) processes, which would also result in the materials 16, 18 being deposited on the surface of the insulator material 12. In embodiments, the high-k gate dielectric material 16 can be deposited on the sidewalls and a bottom of the cavities 14a, 14b, followed by a p-type workfunction material 18, e.g., TiN. In embodiments, the high-k dielectric gate material 16 can be a hafnium based dielectrics, as an example. In further embodiments, examples of such high-k dielectrics include, but are not limited: Al₂O₃, Ta₂O₃, TiO₂, La₂O₃, SrTiO₃, LaAlO₃, ZrO₂, Y₂O₃, Gd₂O₃, and combinations including multilayers thereof. The workfunction material 18 can be any p-type workfunction material, e.g., TiN, TaN, combinations thereof, etc., deposited to a thickness of about 10 Å to about 100 Å. It should be understood by those of skill in the art that the thickness of the high-k dielectric gate material 16 and the p-type workfunction material 18 can vary based on the dimensions of the cavities 14a, 14b.

FIG. 1 further shows a sacrificial dummy gate material fill process. More specifically, remaining portions of the cavities 14a, 14b can be filled with sacrificial dummy gate material 20. In embodiments, the sacrificial dummy gate material 20, e.g., a-Si material, can hold room for later low resistance electrode filling. In embodiments, the sacrificial dummy gate material 20 can be, e.g., a-Si, a-C, spin-coating a-C, DUO (e.g., organo-siloxane (RxCH3ySiOz) polymer (R=organic chromophore)), or SiOH, as examples. Any residual sacrificial dummy gate material 20 outside of the cavities 14a, 14b can be removed by conventional chemical mechanical polishing (CMP) processes which will stop on the p-type workfunction material 18. It should be recognized that the sacrificial dummy gate material 20, e.g., a-Si, can be easily removed without damaging the p-type workfunction material 18. In alternative embodiments, the residual sacrificial dummy gate material 20 outside of the cavities 14a, 14b can also be removed by a selective etching process, with an end point at the high-k dielectric material 16.

FIGS. 2A and 2B show alternative structures and respective fabrication processes in accordance with aspects of the present disclosure. In FIG. 2A, the sacrificial dummy gate material 20 and the p-type workfunction material 18 can be removed from the cavity 14a (e.g., nFET cavity) using conventional lithography and etching processes. For example, after depositing and patterning a blocking resist over the materials on the pFET side of the device, e.g., in the cavity 14b, the sacrificial dummy gate material 20 and the p-type workfunction material 18 on the nFET side of the device, e.g., including within the cavity 14a, can be removed with chemistries selective to such materials. In embodiments, the p-type workfunction material 18 can be removed by a wet etching process. In this way, the high-k dielectric gate material 16 will remain within the cavity 14a for subsequent gate build processes on the nFET side of the structure. After the etching processes are complete, the blocking resist can be removed by conventional stripant processes known to those of skill in the art, e.g., oxygen ashing, etc.

In the alternative embodiment of FIG. 2B, for example, the p-type workfunction material 18 and the high-k dielectric gate material 16 can be recessed within the cavity 14a using selective etch chemistries. In embodiments, the materials 16, 18 can be recessed with the sacrificial dummy gate material 20, followed by the removal of the sacrificial dummy gate material 20. Following the recessing process, the remaining the p-type workfunction material 18 can be removed from the cavity 14a as already described herein. As the high-k dielectric gate material 16 is now recessed, additional space is created in the cavity 14a for additional conductive fill material. In this way, the upper portion of the cavity 14a will have a larger volume for conductive fill material, e.g., tungsten, than in a lower portion of the cavity 14a.

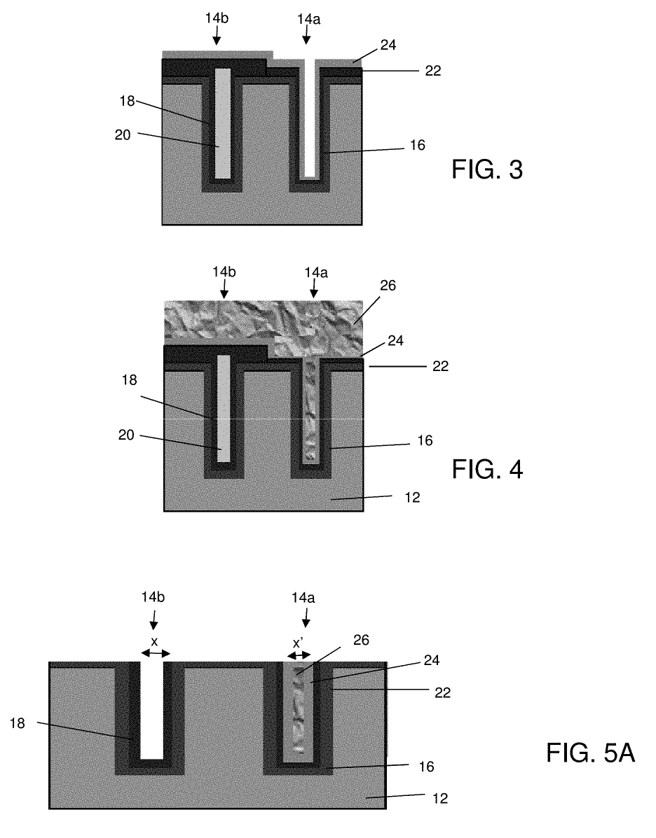

In FIG. 3, an n-type workfunction diffusion barrier material 22 is deposited within the cavity 14a and on the high-k dielectric gate material 16, as well as over the remaining (non-removed) p-type workfunction material 18 outside of the cavity 14a. In embodiments, the n-type workfunction diffusion barrier material 22 can be optional. For example, using some metal workfunction material, the diffusion barrier material 22 is not required to block diffusion of n-type workfunction metal 24, which is deposited on the n-type workfunction diffusion barrier material 22. Both the n-type workfunction diffusion barrier material 22 and the n-type workfunction metal 24 can be deposited using conventional deposition processes, e.g., atomic layer deposition (ALD). The n-type workfunction diffusion barrier material 22 can be, e.g., Co, Ru, Ta, W, Ni or Ti as some examples. The n-type workfunction metal 24 can be, e.g., TiN, TaN, combinations thereof, etc. Although FIG. 3 shows that the materials 22, 24 are provided in the cavity shown in FIG. 2A, it should be understood that the deposition of materials 22, 24 can equally be provided within the cavity of FIG. 2B.

In FIG. 4, a gate metal 26 is deposited on the n-type workfunction metal 24, completely filling the cavity 14a. More specifically, in embodiments, a low resistance fill material, e.g., a tungsten barrier and tungsten fill material 26, is deposited on the n-type workfunction metal 24 within the cavity 14a using conventional deposition processes, e.g., CVD, etc. In embodiments, the tungsten barrier and tungsten fill material 26 will completely fill the cavity 14a.

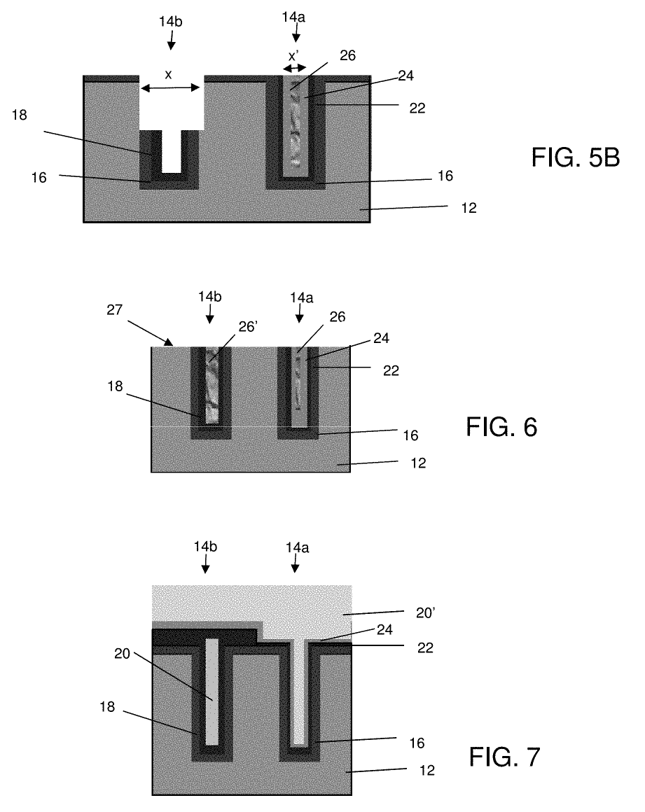

FIGS. 5A and 5B show alternative structures and respective fabrication processes in accordance with aspects of the present disclosure. In either FIG. 5A or FIG. 5B, the sacrificial dummy gate material 20 is removed from the cavity 14b (e.g., pFET cavity) using conventional etching processes, leaving the p-type workfunction material 18 and the high-k dielectric gate material 16 within the cavity 14b for subsequent gate build processes on the pFET side of the device. In the alternative embodiment of FIG. 5B, for example, the layers of material 16, 18 can also be recessed within the cavity 14b using selective etch chemistries. In this way, the top portion of materials 16, 18 can be removed to allow additional space on the pFET side of the device. That is, the upper portion of the cavity 14b will have a larger volume for conductive fill material, e.g., tungsten, than in a lower portion of the cavity 14b.

In either embodiment of FIG. 5A or 5B, it should be recognized that the sacrificial dummy gate material 20, e.g., a-Si, can be easily removed without damaging the p-type workfunction material 18. Moreover, as shown in FIGS. 5A and 5B, the opening (e.g., dimension “x”) of the cavity 14b is larger than the opening (e.g., dimension “x”) of the cavity 14a, resulting in a larger volume for metal fill in the cavity 14b (compared to the cavity 14a). This larger volume of metal fill in the cavity 14b will effectively decrease gate resistance, as well as allow tuning of the pFET device vs. the nFET device, i.e., allow the pFET device to reach its targeted Vt due to the increased volume of work function (WF) material.

As shown in FIG. 6, a gate metal 26′ is deposited on the p-type workfunction metal 18 within the cavity 14b. In embodiments, the gate metal 26′ is a low resistance metal, e.g., a tungsten barrier and tungsten fill material, deposited on the p-type workfunction metal 18 which completely fills the cavity 14b. As the dimension of cavity 14b for filling with metal gate metal is larger than that of the cavity 14a (due to the deposition of materials 16, 22, 24 in the cavity 14a), additional tungsten barrier and tungsten fill material 26′ can be formed within the cavity 14b, which forms the pFET device. This will effectively lower the gate resistance of the pFET device.

In embodiments, the tungsten barrier and tungsten fill material 26′ can be deposited using conventional deposition processes, e.g., CVD, etc. Any residual material formed outside of the cavities 14a, 14b can be removed by a conventional CMP process, resulting in a planar surface 27. Following the steps described herein, conventional processes can follow to complete the devices, e.g., Middle-of-line process, and contact formation, etc., as is well known in the art such that further explanation is not required herein for a complete understanding of the present disclosure.

FIGS. 7-10 show alternative embodiments and respective fabrication processes in accordance with aspects of the present disclosure. More particularly, FIGS. 7-10 show a dual sacrificial-dummy gate process, compared to a single sacrificial-dummy gate process described with respect to FIGS. 1-6. In either embodiments, it should be understood that the removal of the sacrificial-dummy gate will enlarge the space required for gate conduction material, hence providing a lower gate resistance.

More specifically, starting from the structure shown in FIG. 3, in FIG. 7, a sacrificial dummy gate material 20′ is formed over the n-type workfunction metal 24, filling the cavity 14a. In embodiments, the sacrificial dummy gate material 20′ can be, e.g., a-Si, a-C, spin-coating a-C, DUO, or SiOH, as examples. The sacrificial dummy gate material 20′ can be deposited using a conventional deposition process, e.g., CVD processes.

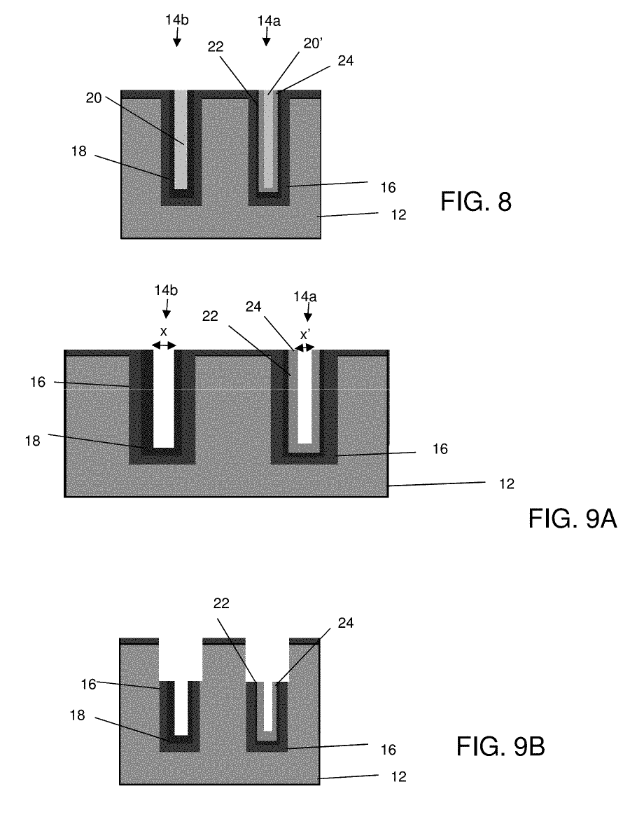

In FIG. 8, any residual sacrificial dummy gate material 20′ outside of the cavities 14a, 14b can be removed by conventional chemical mechanical polishing (CMP) processes and/or wet etching processes. Addition materials outside of the cavities 14a, 14b will also be removed in this removal process. For example, the p-type workfunction material 18, the n-type workfunction diffusion barrier material 22 and the n-type workfunction metal 24 can be removed from the surface of the structure, leaving the high-k dielectric material 16. In this way, the high-k dielectric material 16, the p-type workfunction material 18 and the sacrificial dummy gate material 20 will remain in the cavity 14b (e.g., pFET cavity); whereas, the high-k dielectric material 16, the n-type workfunction diffusion barrier material 22, the n-type workfunction metal 24 and the sacrificial dummy gate material 20 will remain in the cavity 14a (e.g., nFET cavity).

FIGS. 9A and 9B show alternative structures and respective fabrication processes in accordance with aspects of the present disclosure. In FIGS. 9A and 9B, the sacrificial dummy gate material 20, 20′ can be removed from the cavities 14b, 14a (e.g., pFET cavity) using conventional etching processes. In this way, the high-k dielectric material 16, the n-type workfunction diffusion barrier material 22, and the n-type workfunction metal 24 will remain in the cavity 14a; whereas, the high-k dielectric material 16 and the p-type workfunction material 18 will remain in the cavity 14b (e.g., pFET cavity).

In the alternative embodiment of FIG. 9B, for example, the layers of material 16, 18, 22 and 24 can be recessed within the respective cavities 14a, 14b using selective etch chemistries. In embodiments, the materials 16, 18, 22 and 24 can be recessed with the sacrificial dummy gate materials 20, 20′, followed by the removal of the sacrificial dummy gate materials 20, 20′. In this way, the upper portion of each of the cavities 14a, 14b will have a larger volume for conductive fill material, e.g., tungsten, than in a lower portion of the respective cavities 14a, 14b.

In either embodiment, it should be recognized that the sacrificial dummy gate material 20, 20′, e.g., a-Si, can be easily removed without damaging the p-type workfunction material 18 or the n-type workfunction material 24. Also, as described with respect to FIGS. 5A and 5B, the opening (e.g., dimension “x”) of the cavity 14b is larger than the opening (e.g., dimension “x”) of the cavity 14a, resulting in a larger volume for metal fill in the cavity 14b (compared to the cavity 14a). This larger volume of metal fill in the cavity 14b will effectively decrease gate resistance, as well as allow tuning of the pFET device vs. the nFET device, i.e., allow the pFET device to reach its targeted Vt due to the increased volume of work function (WF) material.

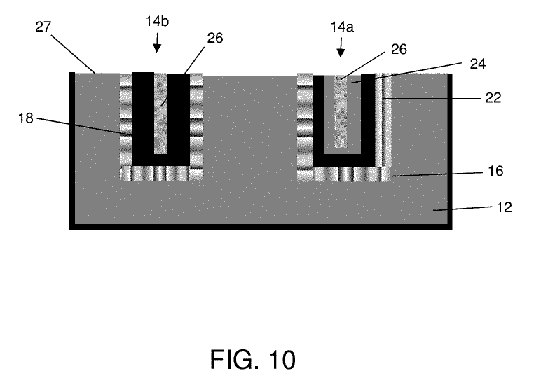

As shown in FIG. 10, a gate metal 26 in both the cavities 14a, 14b. More specifically, in cavity 14a, the gate metal 26 is deposited on the n-type workfunction metal 24; whereas, in cavity 14b, the gate metal 26 is deposited on the p-type workfunction metal 18. In embodiments, the gate metal 26 is a tungsten barrier and tungsten fill material which completely fills the cavities 14a, 14b. As the dimension (volume) of cavity 14b is larger than that of the cavity 14a, additional tungsten barrier and tungsten fill material 26 can be formed within the cavity 14b, which forms the pFET device. This will effectively lower the gate resistance of the pFET device and allow the pFET to reach its targeted Vt.

In embodiments, the tungsten barrier and tungsten fill material 26 can be deposited using conventional deposition processes, e.g., CVD, etc. Any residual material formed outside of the cavities 14a, 14b can be removed by a conventional CMP process, resulting in a planar surface 27. Following the steps described herein, conventional processes can follow to complete the devices, e.g., source and drain formation, contact formation, etc., as is well known in the art such that further explanation is not required herein for a complete understanding of the present disclosure.

As should be recognized, the structures and methods disclosed herein provide many advantages including, amongst others:

(i) the structures and methods can be applied to both nFET first or pFET first schemes;

(ii) the methods provides flexible application for both single and dual sacrificial-dummy gate fabrication processes for nFET and pFET devices.

(iii) the fabrication processes use existing processes of record with the insertion of CMP steps and wet steps, and without introducing any additional patterning steps; and

(iv) the fabrication process can use a WF fill compatible with current process of record gate stacks, e.g., TaN, TiN, etc.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A structure, comprising:
an nFET device formed in a first cavity having a first volume which is filled with conductive material; and
a pFET device forming in a second cavity having a second volume greater than the first volume, the second volume being filled with the conductive material.

2. The structure of claim 1, wherein the conductive material is tungsten material for both the nFET device and the pFET device.

3. The structure of claim 2, wherein the conductive material of the pFET device has a lowered gate resistance compared to the nFET device.

4. The structure of claim 3, further comprising a dielectric layer lining the first cavity and the second cavity, under the conductive material.

5. The structure of claim 4, further comprising an n-type workfunction material lining the first cavity, underneath the conductive material in the first cavity.

6. The structure of claim 5, further comprising an n-type diffusion barrier layer located between the dielectric layer and the n-type workfunction material.

7. The structure of claim 4, further comprising a p-type workfunction material in the second cavity below the conductive material.

8. The structure of claim 7, wherein the p-type workfunction material is between the dielectric layer and the conductive material.

9. The structure of claim 8, wherein the dielectric layer is a high-k dielectric material.

10. A structure, comprising:
an nFET device in a first cavity having an n-type diffusion barrier material, an n-type workfunction metal and a first volume of conductive fill material; and
a pFET device in a second cavity having p-type workfunction metal and a second volume of conductive fill material which is greater than the first volume of the conductive fill material.

11. The structure of claim 10, wherein the conductive fill material is tungsten material for both the nFET device and the pFET device.

12. The structure of claim 11, wherein the conductive fill material of the pFET device has a lowered gate resistance compared to the nFET device.

13. The structure of claim 12, further comprising a dielectric layer lining the first cavity and the second cavity, under the conductive fill material, wherein the n-type workfunction material is underneath the conductive fill material in the first cavity and the p-type workfunction material is between the dielectric layer and the conductive fill material in the second cavity.

14. The structure of claim 13, wherein the dielectric layer is a high-k dielectric material.

15. The structure of claim 13, wherein the dielectric layer partially extends on a sidewall of the first cavity and the n-type diffusion barrier material, the n-type workfunction metal and the first volume of conductive fill material fills remaining portions of the first cavity.

16. The structure of claim 13, wherein the dielectric layer and the p-type workfunction metal extends partially on a sidewall of the second cavity and the conductive fill material fills remaining portions of the second cavity.

17. The structure of claim 16, wherein the conductive fill material has a greater volume in an upper portion of the second cavity than in a lower portion of the second cavity.

18.-20. (canceled)

21. The structure of claim 1, wherein the first cavity includes sidewalls that are fully lined with dielectric material and the second cavity includes sidewalls that are partially or fully lined with dielectric material.

22. The structure of claim 1, wherein the first cavity includes sidewalls that are partially lined with dielectric material and the second cavity includes sidewalls that are partially or fully lined with dielectric material.

23. The structure of claim 10, wherein a volume of the first cavity is different than the volume of the second cavity.
